(19) United States
(12) Patent Application Publication
(10) Pub. No.: US 2010/0273325 A1
(43) Pub. Date: Oct. 28, 2010

(54) METHOD OF MANUFACTURING SEMICONDUCTOR DEVICE

(75) Inventor: Kazuo YAMAZAKI, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/762,821

(22) Filed: Apr. 19, 2010

(30) Foreign Application Priority Data
Apr. 22, 2009 (JP) 2009-104420

(51) Int. Cl. H01L 21/768; H01L 21/033

(52) U.S. Cl. 438/666; 438/761; 257/E21.035; 257/E21.585

(57) ABSTRACT

A method of manufacturing a semiconductor device may include, but is not limited to the following processes. A mask layer is formed over a gate electrode portion and a wiring portion adjacent to the gate electrode portion. The mask layer includes a first portion covering the wiring portion. Then, at least a part of the first portion is removed.

### BACKGROUND OF THE INVENTION

1. Field of the Invention

The present invention relates to a method of manufacturing a semiconductor device.

Priority is claimed on Japanese Patent Application No. 2009-104420, filed Apr. 22, 2009, the content of which is incorporated herein by reference.

2. Description of the Related Art

Japanese Patent Laid-Open Publication No. 2005-72167 discloses a semiconductor device, such as DRAM (Dynamic Random Access Memory), which includes a gate hard mask including a silicon nitride film covering a gate electrode portion. A gate inter-layer insulating film including a silicon oxide film or the like is formed so as to cover a gate wiring layer including the gate electrode portion and the gate hard mask.

Then, a contact plug hole is formed by self-alignment in the gate inter-layer insulating film. Then, a metal film made of tungsten or the like is formed over the gate inter-layer insulating film. Then, the metal film is planarized by CMP (Chemical Mechanical Polishing) to form a contact plug in the contact plug hole. In this case, the gate hard mask is also polished during the CMP process.

Then, an inter-layer insulating film including a silicon oxide film or the like is formed by CVD (Chemical Vapor Deposition). Then, a capacity contact hole is formed by etching in the inter-layer insulating film. Then, a capacity contact plug, which will be electrically connected to the contact plug, is formed in the capacity contact hole.

Japanese Patent Laid-Open Publication No. 2007-287794 discloses a semiconductor device having a 6F² cell structure in which the center position of a capacity contact plug is purposely displaced from the center position of a contact plug toward a gate electrode portion.

However, when the polishing rate differs depending on a position on a surface to be polished, i.e., when the polishing rate is greater at one position than at another position, the gate hard mask is excessively polished to be very thin at the one position. In this case, the gate hard mask is also etched while etching the capacity contact hole in the following process, and thereby the underlying gate electrode is occasionally exposed.

When the center position of a capacity contact plug 43 is purposely displaced from the center position of a contact plug 44 toward a gate electrode portion 42 as shown in FIGS. 11 and 12, an edge portion of a gate hard mask 40 is likely to be etched, and thereby the gate electrode portion 42 is likely to be exposed.

If the capacity contact plug 43 is formed in the capacity contact hole 41 when the gate electrode portion 42 is exposed, a short-circuit between the gate electrode portion 42 and the capacity contact plug 43 occurs.

### SUMMARY

In one embodiment, a method of manufacturing a semiconductor device may include, but is not limited to the following processes. A mask layer is formed over a gate electrode portion and a wiring portion adjacent to the gate electrode portion. The mask layer comprises a first portion covering the wiring portion. Then, at least a part of the first portion is removed.

In another embodiment, a method of manufacturing a semiconductor device may include, but is not limited to the following processes. A first insulating film is formed over a gate electrode portion and a wiring portion adjacent to the gate electrode portion. An etching stopper film is formed over the first insulating film. A second insulating film is formed over the etching stopper film. A stack of the first insulating film, the etching stopper film, and the second insulating film includes a first portion covering the wiring portion. At least a part of the first portion is removed while the first insulating film remains.

In still another embodiment, a method of manufacturing a semiconductor device may include, but is not limited to the following processes. A gate electrode portion is formed. A first insulating film is formed over the gate electrode portion. An etching stopper film is formed over the first insulating film. A second insulating film is formed over the etching stopper film. The gate electrode portion, the first insulating film, the etching stopper film, and the second insulating film form a structure. A contact plug is formed adjacent to the structure. A third insulating film is formed over the structure and the contact plug. The third insulating film is etched to form a capacity contact plug electrically connected to the contact plug.

Accordingly, a short-circuit between the gate electrode portion and the capacity contact plug can be prevented.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view illustrating a gate-wiring formation process included in a method of manufacturing a semiconductor device according to a first embodiment of the present invention;

FIG. 2 is a plane view illustrating a contact-plug formation process included in the method;

FIG. 3 is a cross-sectional view taken along a line A-A′ shown in FIG. 2;

FIG. 4 is a plane view illustrating an etching-resistance-film removal process included in the method;

FIG. 5 is a cross-sectional view taken along a line B-B′ shown in FIG. 4;

FIG. 6 is a plane view illustrating the etching-resistance-film removal process included in the method;

FIG. 7 is a cross-sectional view taken along a line C-C′ shown in FIG. 6;

FIG. 8 is a cross-sectional view taken along a line D-D′ shown in FIG. 6;

FIG. 9 is a plane view illustrating a capacity-contact-plug formation process included in the method;

FIG. 10 is a cross-sectional view illustrating a cross-section taken along a line E-E′ shown in FIG. 9;

FIG. 11 is a plane view illustrating a conventional capacity-contact-plug formation process; and

FIG. 12 is a cross-sectional view illustrating a cross-section taken along a line F-F′ shown in FIG. 11.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

According to a method of manufacturing a semiconductor device of a first embodiment of the present invention, a gate hard mask including an etching resistance film is formed over multiple gate wiring portions, and wiring portions each connecting two adjacent gate wiring portions. Then, the etching resistance film covering the wiring portions is removed.

Hereinafter, the method of the first embodiment is explained in detail. The method of the first embodiment explains a case where DRAM is used as a semiconductor device. The method includes a gate-wiring formation process, a contact-plug formation process, an etching-resistance-film removal process, and a capacity-contact-plug formation process. Each of the above processes is specifically explained hereinafter.

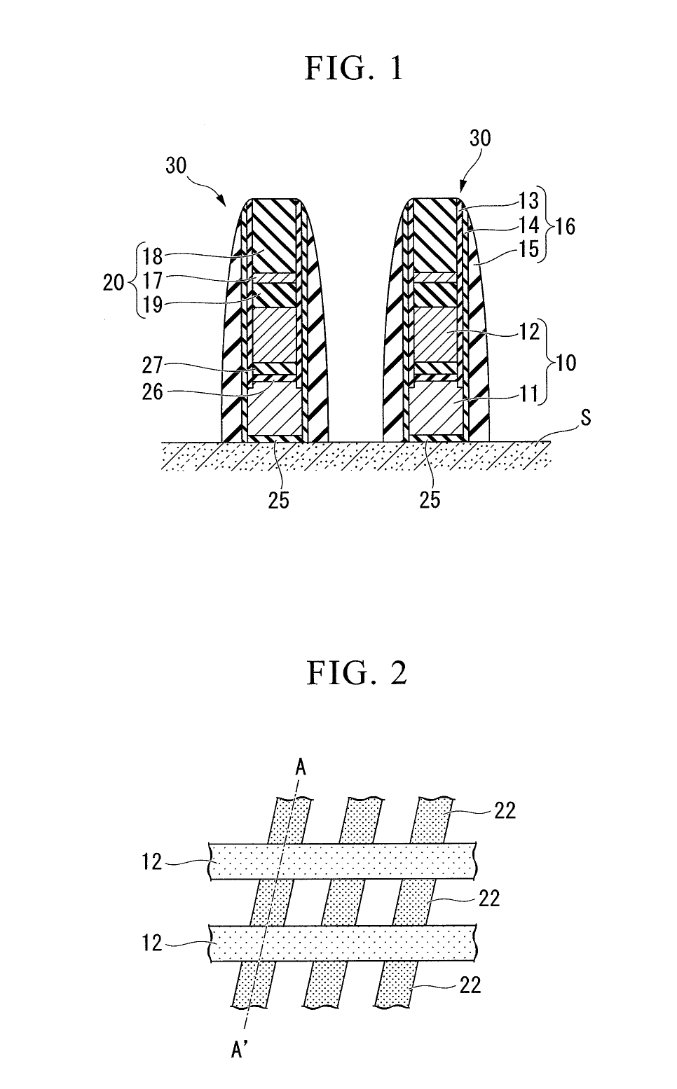

FIG. 1 is a cross-sectional view illustrating a gate wiring 30 formed in the gate-wiring formation process. A semiconductor device manufactured by the method of the first embodiment includes multiple gate wirings 30 arranged in substantially parallel.

In the gate-wiring formation process, a gate insulating film 25 including a silicon oxide film or the like is formed by thermal oxidization or the like over a semiconductor substrate S, such as a silicon substrate. Then, a poly-silicon film 11, and a metal film 12 made of tungsten or the like are formed over the gate insulating film 25, as a conductive film forming a gate electrode portion 10 and a wiring portion (not shown).

Additionally, in this case, a tungsten silicide film 26 and a tungsten nitride film 27 both having a thickness of, for example, 10 nm are formed between the poly-silicon film 11 and the metal film 12, as a barrier film. The tungsten silicide film 26 is formed by LP-CVD (Low Pressure Chemical Vapor Deposition). The tungsten nitride film 27 is formed by sputtering.

Then, a gate hard mask 20 is formed over the conductive film forming the gate electrode portion 10 and the wiring portion. The gate hard mask 20 includes insulating films 18 and 19, and an etching resistance film 17 between the insulating films 18 and 19. For example, a silicon nitride film and a silicon oxide film are used as the insulating films 18 and 19, respectively.

In this case, the gate hard mask 20 has a four-layered structure including a silicon nitride film, an etching resistance film 17, a silicon nitride film, and a silicon oxide film, which are sequentially deposited from the side of the gate electrode portion 10. The etching resistance film 17 includes a metal film made of tungsten or the like. The etching resistance film 17 serves as a stopper film having an etching resistance.

The silicon nitride film and the silicon oxide film of the gate hard mask 20 are formed by plasma CVD. The etching resistance film is formed by sputtering. The silicon oxide film has a thickness of, for example, 100 nm. The silicon nitride film has a thickness of, for example, 200 nm. Since the etching resistance film 17 is hardly etched, the etching resistance film 17 serves well as a stopper film if the etching resistance film 17 has a thickness of 20 to 50 nm.

The etching resistance film 17 is disposed between the insulating films 18 and 19. Preferably, the level of a bottom surface of the etching resistance film 17 is 20 nm above the level of a bottom end of the gate hard mask 20 (on the bottom side of the gate electrode portion 10). Further, the level of an upper surface of the etching resistance film 17 is below the level of the center position of the gate hard mask 20.

If the level of the bottom surface of the etching resistance film 17 is 20 nm above the level of the bottom end of the gate hard mask 20, the gate electrode 10 is well insulated from the etching resistance film 17. If the upper surface of the etching resistance film 17 is lower in level than the center position of the gate hard mask 20, even if the gate hard mask 20 is polished by CMP in the contact-plug formation process as explained later, the etching resistance film 17 remains without being polished, and therefore serves well as a stopper film.

Then, these layers are patterned by photolithography and etching to form a gate pattern on the semiconductor substrate S. The silicon oxide film included in the gate hard mask 20 is etched using a parallel plate etching apparatus or the like under conditions such that CF₄/Ar=100/200 ml/min, the pressure is 100 mTorr, and the RF power is 1000 W.

The silicon nitride film included in the gate hard mask 20 is etched using a parallel plate etching apparatus under conditions such that CF₄/CHF₃/Ar/O₂=100/100/100/200 ml/min, the pressure is 100 mTorr, and the RF power is 1000 W.

If the etching resistance film 17 is made of tungsten, the etching resistance film 17 is etched by a microwave plasma etching apparatus under conditions such that Cl₂/SF₆=150/50 ml/min, the pressure is 10 mTorr, the microwave power is 1000 W, and the RF power is 20 W.

The conductive film including the gate electrode potion 10 and the wiring portion is etched using a microwave plasma etching apparatus or the like. The metal film made of tungsten or the like is etched under conditions such that Cl₂/SF₆=150/50 ml/min, the pressure is 10 mTorr, the microwave power is 1000 W, and the RF power is 20 W.

The poly-silicon film 11 is subsequently etched using the same microwave plasma etching apparatus under conditions such that HBr/O₂=200/10 ml/min, the pressure is 10 mTorr, the microwave power is 1000 W, and the RF power is 20 W.

In this case, after the metal film 12 is etched, before the poly-silicon film 11 is etched, a silicon nitride film having a thickness of, for example, 10 nm is formed by LP-CVD. Then, a portion of the silicon nitride film, which covers the poly-silicon film 11, is etched. Thus, a silicon nitride film 13 covering side surfaces of the gate electrode 10 and the wiring portion is formed.

Then, a silicon oxide film 14 having a horizontal thickness of, for example, 5 nm is formed by thermal oxidization so as to cover the silicon nitride film 13. Then, a silicon nitride film 15 having a horizontal thickness of, for example, 20 nm is formed by LP-CVD.

Thus, a sidewall 16, which has a three-layered structure including the silicon nitride film 13, the silicon oxide film 14, and the silicon nitride film 15, is formed so as to cover the side surfaces of the gate electrode portion 10 and the wiring portion (not shown). Additionally, the gate hard mask 20 is deposited over the gate electrode portion 10 and the wiring portion. Thus, a gate wiring 30 having the above structure can be formed.

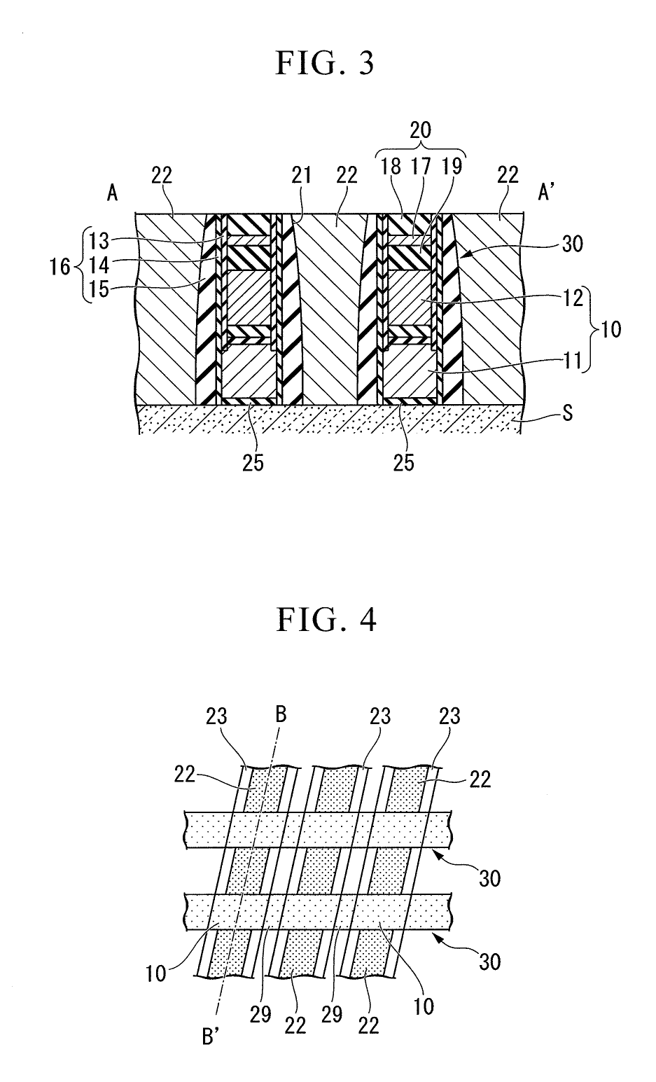

FIG. 2 is a plane view illustrating a contact plug 22 formed in the contact-plug formation process. FIG. 3 is a cross-sectional view taken along a line A-A′ shown in FIG. 2. The contact plug 22 will be electrically connected to a source-or-drain region (not shown).

After the gate wiring 30 is formed, a gate inter-layer insulating film (first inter-layer insulating film) is formed so as to cover the gate wiring 30. Preferably, a silicon oxide film, which can be easily embedded, is used as the gate inter-layer insulating film. For example, a method of forming an SOG (Spin On Glass) film and then carrying out an annealing process for planarization, a method of forming an O3-TEOS (tetraethylorthosilicate) film and then carrying out an annealing process for planarization, a method of forming a BPSG (boronphosphosilicate glass) film and then carrying out an annealing process for planarization, or an HDP (High Density Plasma) method, is used.

After the gate inter-layer insulating film is formed, a contact plug hole 21 is formed by self-alignment in the gate inter-layer insulating film. The self-alignment etching process is carried out using a two-frequency parallel plate etching apparatus under conditions such that C₄F₆/Ar/O₂=20/1000/20 ml/min, the pressure is 20 mTorr, the upper the RF power is 1000 W, and the lower RF power is 2000 W.

After the contact plug hole 21 is formed, a contact-plug formation film for forming the contact plug 22 is formed over the entire surface. Then, the contact-plug formation film is etched by CMP to form the contact plug 22 in the contact plug hole 21.

During the CMP process, not only the contact-plug formation film, but also a part of the insulating film 18 of the gate hard mask 20 covered by the contact-plug formation film is polished. Consequently, the insulating film 18 becomes thinner. A metal film made of tungsten formed by CVD is used as the contact-plug formation film.

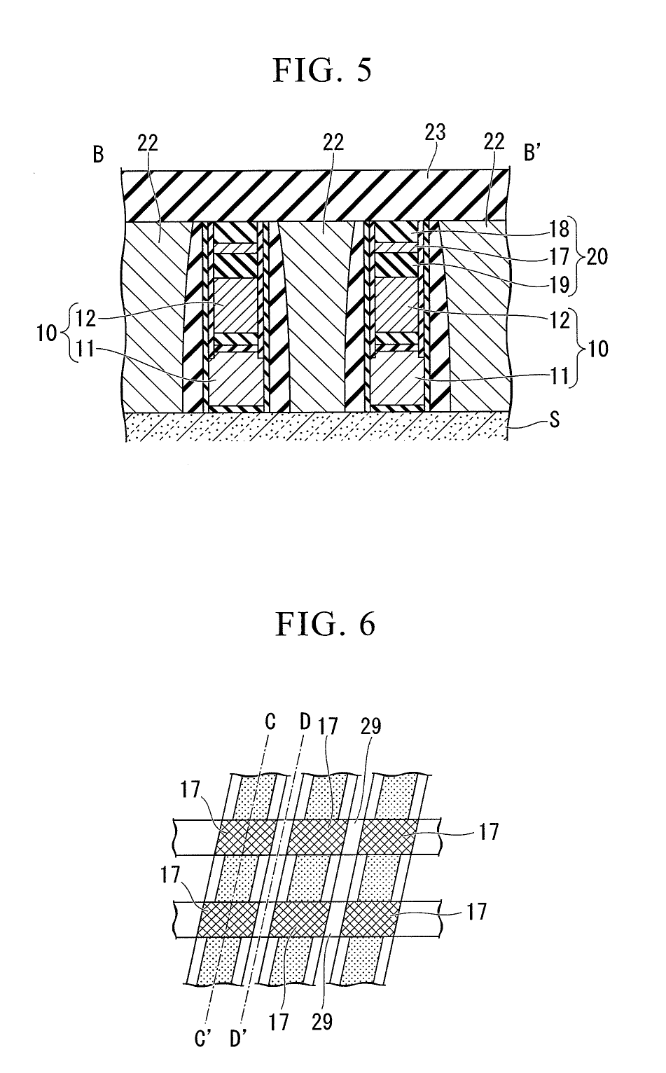

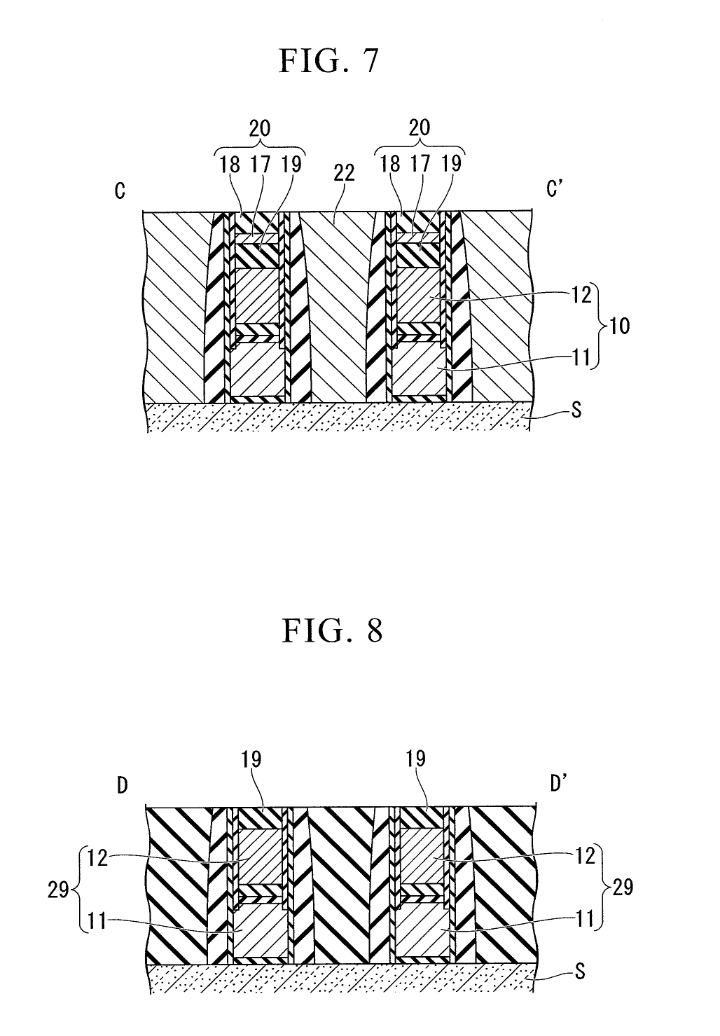

FIG. 4 is a plane view illustrating the etching-resistance removal process. FIG. 5 is a cross-sectional view taken along a line B-B′ shown in FIG. 4. FIG. 6 is a plane view illustrating a state of the etching resistance film 17 covering a wiring portion 29 being removed. FIG. 7 is a cross-sectional view taken along a line C-C′. FIG. 8 is a cross-sectional view taken along a line D-D′ shown in FIG. 6.

After the contact plug 22 is formed in the contact-plug formation process, the etching resistance film 17 covering the wiring potion 29 is removed by photolithography and etching. Thus, the etching resistance film 17 can be divided so as not to electrically connect capacity contact plugs which will be formed later.

Specifically, a photoresist film 23 is patterned so that the gate hard mask 20 covering the wiring portion 29 is exposed, the gate hard mask 20 covering the gate electrode portion 10 is covered by the photoresist film 23, and the photoresist film 23 crosses the gate wiring 30 in plane view, as shown in FIGS. 4 and 5. Then, the etching resistance film 17, and the silicon nitride film that is the insulating film 18 are etched.

After the etching, the etching resistance film 17 remains above each gate electrode portion 10, as shown in FIG. 7. On the other hand, only the insulating film 19 of the gate hard mask 20 remains above the wiring portion 29, and the etching resistance film 17 covering the wiring portion 29 is completely removed, as shown in FIG. 8. Thus, the etching resistance film 17 is divided between each of the gate electrode portions 10, and each etching resistance film piece 17 is isolated above each gate electrode 10.

The etching conditions used for etching the silicon nitride film and the etching resistance film, which has been explained in the gate-wiring formation process, can be used here. The purpose of this etching is to divide the etching resistance film 17 so as not to electrically connect capacity contact plugs. Therefore, a small amount of the etching resistance film remaining above the wiring portion 29 is not problematic as long as the purpose is fulfilled.

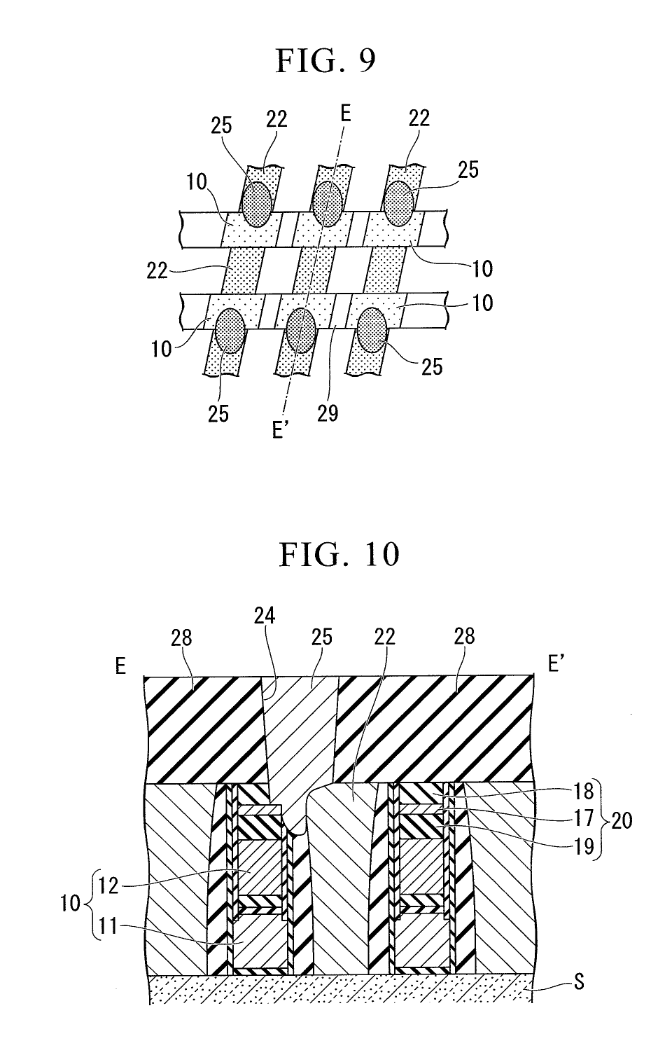

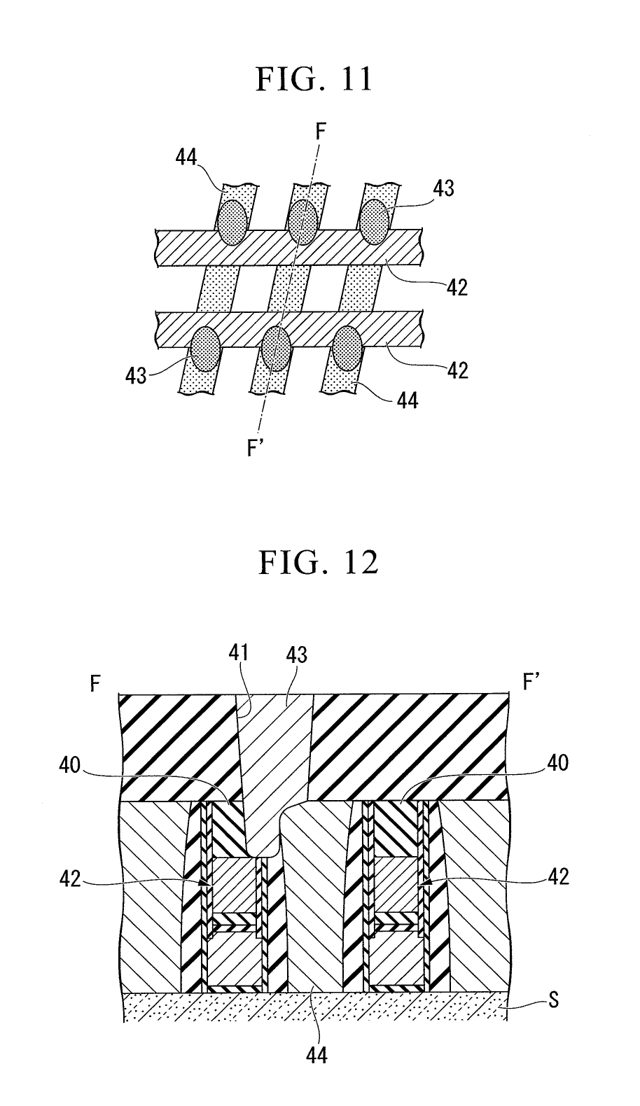

FIG. 9 is a plane view illustrating a state of a capacity contact plug being formed in the capacity contact hole in the capacity-contact-plug formation process. FIG. 10 is a cross-sectional view illustrating a cross-section taken along a line E-E′ shown in FIG. 9.

As shown in FIGS. 9 and 10, the center position of the capacity contact plug 25 is purposely displaced from the center position of the contact plug 22 toward the gate electrode portion 10. This layout is preferably used for the 6F² cell structure.

After the etching resistance film 17 covering the wiring portion 29 is removed in the etching-resistance-film removal process, an inter-layer insulating film (second inter-layer insulating film) 28 is formed so as to cover the contact plug 22. Specifically, although not shown, a lower inter-layer insulating film is formed by plasma CVD. Then, a bit contact (not shown) and a bit line (not shown) are formed. Then, an upper inter-layer insulating film is formed over the lower inter-layer insulating film to form the inter-layer insulating film 28 having a two layered structure.

Similar to the gate inter-layer insulating film, a silicon oxide film, which can be easily embedded, is preferably used as the upper inter-layer insulating film. For example, a method of forming an SOG film and then carrying out an annealing process for planarization, a method of forming an O3-TEOS film and then carrying out an annealing process for planarization, a method of forming a BPSG film and then carrying out an annealing process for planarization, or an HDP method, is used to form the silicon oxide film.

After the inter-layer insulating film 28 is formed, a capacity contact hole 24 is formed by self-alignment in the inter-layer insulating film 28. The self-alignment etching is carried out using a two frequency parallel plate etching apparatus under conditions such that C₄F₆/Ar/O₂=20/1000/20 ml/min, the pressure is 20 mTorr, the upper RF power is 1000 W, and the lower RF power is 2000 W.

Then, a capacity contact plug 25 made of poly-silicon or the like is formed in the capacity contact hole 24. The capacity contact plug 25 is electrically connected to the contact plug 22.

As explained above, according to the method of the first embodiment, the gate hard mask 20 including the etching resistance film 17 is formed over the gate electrode portion 10 and the wiring portion 29. Then, the etching resistance film 17 covering the wiring portion 29 is removed so that each etching resistance film piece 17 is isolated above each gate electrode portion 10.

Thanks to the gate hard mask 20 including the etching resistance film 17 being above the gate electrode portion 10, a short-circuit between the gate electrode portion 10 and the capacity contact plug 25 can be prevented when the capacity contact plug 25 is formed in the capacity contact hole 24.

In other words, if the gate hard mask 20 includes the etching resistance film 17, the etching for forming the capacity contact hole 24 stops at the etching resistance film 17, and does not proceed further. For this reason, even if the gate hard mask 20 has a possibility of being thinner by CMP, the etching stops at the etching resistance film 17, and therefore the gate electrode portion 10 is not exposed. Therefore, a short-circuit between the gate electrode portion 10 and the capacity contact plug 25 can be prevented.

Additionally, the etching resistance film 17 covering the wiring portion 29 is completely removed. For this reason, the capacity contact plugs are not electrically connected by the etching resistance film 17.

When the 6F² cell structure is used, the center position of the capacity contact plug 25 is purposely displaced from the center position of the contact plug 22 toward the gate electrode portion 10, as shown in FIGS. 9 and 10. In such a case, an edge portion of the gate hard mask 20 is likely to be etched during an etching process for forming the capacity contact hole 24. For this reason, a short-circuit between the capacity contact plug 25 and the gate electrode portion 10 is more likely to occur.

According to the method of the first embodiment, however, the gate hard mask 20 including the etching resistance film 17 is formed above the gate electrode portion 10. For this reason, even when a semiconductor device having a layout for which a short-circuit is likely to occur between the capacity contact plug 25 and the gate electrode portion 10, the etching resistance film 17 serves as a stopper film, thereby effectively preventing such a short-circuit.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

For example, a semiconductor device according to one embodiment of the present invention may include, but is not limited to: a gate electrode portion; a wiring portion adjacent to the gate electrode portion; a mask covering the gate electrode portion, the mask including a metal film; and an insulating layer adjacent to the mask, the insulating layer covering the wiring portion, and the insulating layer being free of a metal film.

Regarding the semiconductor device of the one embodiment, an upper surface of the metal film is lower in level than a center position of the mask.

Regarding the semiconductor device of the one embodiment, the mask may further include: a first insulating film, the metal film covering the first insulating film; and a second insulating film covering the metal film.

Regarding the semiconductor device of the one embodiment, the first insulating film includes a first silicon nitride film, the metal film includes a tungsten film, and the second insulating film includes a second silicon nitride film and a silicon oxide film over the second silicon nitride film.

The semiconductor device of the one embodiment may further include: a contact plug adjacent to the gate electrode portion and the mask; a sidewall covering side surfaces of the gate electrode portion and the mask, the sidewall insulating the contact plug from the gate electrode portion and the mask; and a capacity contact plug over the contact plug, the capacity contact plug electrically connected to the contact plug, the capacity contact plug being in contact with the mask, and the metal film separating the gate electrode from the capacity contact plug.

A semiconductor device according to another embodiment of the present invention may include, but is not limited to: a first structure including a gate electrode portion and a mask, the mask including a metal film and first and second insulating films, the first film covering the gate electrode portion, the metal film covering the first insulating film, and the second insulating film covering the metal film; and a capacity contact plug over the first structure, the capacity contact plug partially overlapping the first structure in plane view, and the metal film and the first insulating film separating the gate electrode from the capacity contact plug.

The semiconductor device of the another embodiment may further include: a contact plug adjacent to the first structure; and a first sidewall covering a side surface of the first structure, the first sidewall insulating the first structure from the contact plug.

The semiconductor device of the another embodiment may further include: a second structure having the same structure as the first structure; and a second side wall covering a side surface of the second structure. The contact plug is disposed between the first and second structures, and the first and second sidewalls insulate the contact plug from the first and second structures.

Regarding the semiconductor device of the another embodiment, the capacity contact plug is in contact with one of the first and second structures.

Regarding the semiconductor device of the another embodiment, a bottom of the capacity contact plug is lower in level than a lower surface of the metal film, and the bottom of the capacity contact plug is higher in level than an upper surface of the gate electrode portion.

Regarding the semiconductor device of the another embodiment, an upper surface of the metal film is lower in level than a center position of the mask.

What is claimed is:

1. A method of manufacturing a semiconductor device, comprising:
forming a mask layer over a gate electrode portion and a wiring portion adjacent to the gate electrode portion, the mask layer comprising a first portion covering the wiring portion; and
removing at least a part of the first portion.

2. The method according to claim 1, wherein forming the mask layer comprises:
forming a first insulating film over the gate electrode portion and the wiring portion;
forming an etching stopper film over the first insulating film; and
forming a second insulating film over the etching stopper film.

3. The method according to claim 2, wherein
the first insulating film comprises a first silicon nitride film,
the etching stopper film comprises a tungsten film, and
the second insulating film comprises a second silicon nitride film and a silicon oxide film over the second silicon nitride film.

4. The method according to claim 2, wherein removing the at least a part of the first portion comprises removing the second insulating film and the etching stopper film while having the first insulating film remain.

5. The method according to claim 2, further comprising:
before forming the mask layer, forming a conductive layer comprising the gate electrode portion and the wiring portion,
wherein forming the mask layer comprising forming the mask layer over the conductive layer.

6. The method according to claim 5, further comprising:
before removing at least a part of the first portion, patterning a stack of the mask layer and the conductive layer to form at least first and second structures, the first and second structures being remaining portions of the stack.

7. The method according to claim 6, wherein the first structure is distanced from the second structure such that the first and second structures form a line-and-space pattern.

8. The method according to claim 6, further comprising:
forming a contact plug between the first and second structures;
after removing the at least a part of the first portion, forming an insulating layer over the first and second structures and the contact plug; and
etching, while the etching stopper film covers the gate electrode portion, the insulating layer to form a capacity contact plug electrically connected to the contact plug, the capacity contact plug partially overlapping one of the first and second structures in plane view.

9. The method according to claim 8, further comprising:
forming a sidewall covering a side surface of each of the first and second structures, the sidewall insulating each of the first and second structures from the contact plug.

10. The method according to claim 2, wherein an upper surface of the etching stopper film is lower in level than a center position of the mask layer.

11. The method according to claim 8, wherein
the capacity contact plug is in contact with the mask layer included in the one of the first and second structures.

12. The method according to claim 8, wherein
a bottom of the capacity contact plug is lower in level than a lower surface of the etching stopper film, and
the bottom of the capacity contact plug is higher in level than an upper surface of the gate electrode portion.

13. A method of manufacturing a semiconductor device, comprising:
forming a first insulating film over a gate electrode portion and a wiring portion adjacent to the gate electrode portion;
forming an etching stopper film over the first insulating film;
forming a second insulating film over the etching stopper film, a stack of the first insulating film, the etching stopper film, and the second insulating film comprising a first portion covering the wiring portion; and
removing a part of the first portion while having the first insulating film remain.

14. The method according to claim 13, wherein
the first insulating film comprises a first silicon nitride film,
the etching stopper film comprises a tungsten film, and
the second insulating film comprises a second silicon nitride film and a silicon oxide film over the second silicon nitride film.

15. The method according to claim 13, further comprising:
forming a third insulating film so as to fill the removed part of the first portion.

16. The method according to claim 13, wherein the second insulating film is thicker than the first insulating film.

17. A method of manufacturing a semiconductor device, comprising:
forming a gate electrode portion;
forming a first insulating film over the gate electrode portion;
forming an etching stopper film over the first insulating film;
forming a second insulating film over the etching stopper film, wherein the gate electrode portion, the first insulating film, the etching stopper film, and the second insulating film form a structure;
forming a contact plug adjacent to the structure;
forming a third insulating film over the structure and the contact plug; and
etching the third insulating film to form a capacity contact plug electrically connected to the contact plug.

18. The method according to claim 17, wherein the etching stopper film covers the gate electrode portion during etching the third insulating film.

19. The method according to claim 17, wherein the capacity contact plug partially overlaps the structure in plane view.

20. The method according to claim 17, further comprising:
before forming the contact plug, forming a sidewall covering a side surface of the structure, the sidewall insulating the structure from the contact plug.
